(19) United States
(12) Patent Application Publication
(10) Pub. No.: US 2024/0250044 A1
(43) Pub. Date: Jul. 25, 2024

(54) MAGNETIC APPARATUS WITH INTEGRATED PINS AND METALLIZATION PINS, POWER MODULE, AND METHOD OF MAKING

(71) Applicant: SHANGHAI METAPWR ELECTRONICS CO. , LTD, Shanghai (CN)

(72) Inventors: Jianhong ZENG, Shanghai (CN); Yayu LI, Shanghai (CN); Xiangfei KANG, Shanghai (CN)

(73) Assignee: SHANGHAI METAPWR ELECTRONICS CO. , LTD, Shanghai (CN)

(21) Appl. No.: 18/408,453

(22) Filed: Jan. 9, 2024

(30) Foreign Application Priority Data
Jan. 19, 2023 (CN) 202310076520.X

(51) Int. Cl. H01L 23/64; H01F 27/26; H01F 27/28; H01F 27/29; H01F 27/30; H01F 41/02; H01L 23/498

(52) U.S. Cl. CPC H01L 23/645; H01F 27/263; H01F 27/266; H01F 27/2885; H01F 27/292; H01F 27/306; H01L 23/49811; H01F 41/0206

(57) ABSTRACT

A magnetic apparatus with integrated pins and metallization pins includes preformed DC voltage pins, preformed windings, a magnetically permeable core and signal pins, with bonding-pad regions coplanar by means of metallization. A method is used for making it including assembling input pin pieces, windings and a semi-finished magnetically permeable core, carrying out a hot-pressing process, forming openings and metallization. A power module includes the aforementioned magnetic apparatus and IPM units.

### CROSS-REFERENCE TO RELATED APPLICATIONS

This application claims the priority and benefit of Chinese patent application Ser. No. 20/231,0076520.X filed on Jan. 19, 2023. The entirety of the above-mentioned patent application is hereby incorporated by reference herein and made a part of this specification.

### BACKGROUND

Along with the fact that the data processing amount is greatly improved, more and more layers of a mainboard of the server are more and more precious, and the requirement for the occupied area of the power supply is higher and higher. Taking a large number of step-down circuits used by a server as an example, more and more schemes adopt a power supply module mode of stacking a power semiconductor element and a magnetic element to reduce the occupied area.

In addition, other schemes are selected to place the semiconductor on the inductor 15, so that a customer can install the radiator conveniently, and the overall power is improved. In this way, the transmission of the signal and the power in the stacking direction must pass through the inductor 15 to reach the switch tube on the mainboard.

As shown in FIG. 1A, the power semiconductor element of the Buck circuit is composed of two switching devices, and a decoupling capacitor Cin1 needs to be placed nearby to suppress reliability loss caused by voltage spikes. Due to the limitation of the height and space of the module, the capacity of Cin1 is usually relatively small, such as 1 U, which is only used for reducing the loop inductor 15 Lloop 1, so that more capacitor Cin2 needs to be placed at the position close to the module pin for filtering.

FIG. 1B shows a power module with a power pin trace (i.e., an outer wiring 16), a signal pin header and an inductor 15 at the same height. FIG. 1C shows the making method of the outer wiring 16. Firstly, the preformed metal frame is bonded with the body of inductor 15, and then is bent along the upper and the lower edge of the inductor 15 to form effective welding pads respectively. By means of the arrangement, the occupied area of the power pin wiring is small, the utilization rate is very high.

Furthermore, the vertical conduction of the signal pin wiring in FIG. 1B is implemented by a pin header. The metal part of the pin header is attached to a plastic frame, then the pin header is attached to the side surface of the inductor 15, the pins are subsequently electrically connected with the IPM units by welding. In order to ensure the stability of a plurality of signal pins, the thickness L1 of the plastic frame at one side of the metal part is at least 1 mm, and the thickness L2 of the metal part is at least 0.5 mm, so that the size of the whole signal pin header is 2.5 mm.

### SUMMARY

In general, one aspect features an apparatus comprises:
preformed metal pieces comprising DC voltage pins and windings, a magnetically permeable core and signal pins;
wherein the magnetically permeable core is arranged around each at least a part of the windings, and the DC voltage pins are integrated with the magnetically permeable core;
wherein the signal pins are arranged on outer surfaces of the magnetically permeable core through a metallization process; and
wherein the preformed metal pieces and the signal pins are respectively provided with bonding-pad regions and non-pad regions, and the bonding-pad regions on either of an upper surface and a lower surface of the magnetically permeable core are coplanar.

Implementations of the apparatus may include one or more of following features. The non-pad regions of the DC voltage pins are arranged on the selected outer surface or selected outer surfaces of the magnetically permeable core, or are embedded in the magnetically permeable core with a distance of no more than 1 mm to the surface.

Implementations of the apparatus may include one or more of following features. The windings are single-turn windings; and
wherein each of the windings is provided with three vertical sections and two lateral sections which are alternately connected; the distance between the two lateral sections is twice the distance between the upper one of the lateral sections and the upper surface of the magnetically permeable core; and the distance between the two lateral sections is twice the distance between the lower one of the lateral sections and the lower surface of the magnetically permeable core.

Implementations of the apparatus may include one or more of following features. The magnetically permeable core and the preformed metal pieces are integrally formed through a hot-pressing process and annealing treatment.

Implementations of the apparatus may include one or more of following features. The DC voltage pins comprise a ground pin and an input voltage pin, wherein at least a part of the non-pad region of the input voltage pin is overlapped with the non-pad region of the ground pin.

Implementations of the apparatus may include one or more of following features. The DC voltage pins comprises a ground pin, an input voltage pin and a shielding layer, wherein at least a part of the non-pad region of the input voltage pin is overlapped with the shielding layer.

Implementations of the apparatus may include one or more of following features. The shielding layer is provided with a contact region; the ground pin is electrically connected with the contact region; and

Implementations of the apparatus may include one or more of following features. An insulation layer is disposed between the input voltage pin and the shielding layer.

Implementations of the apparatus may include one or more of following features. The DC voltage pins comprises ground pins and input voltage pins which are alternately arranged.

Implementations of the apparatus may include one or more of following features. The non-pad regions of the preformed metal pieces are arranged on at least two side surfaces of the magnetically permeable core; the bonding-pad regions of the preformed metal pieces comprise thick-layer lateral-wiring regions and bonding pads, and the thick-layer lateral-wiring regions are electrically connected with the bonding pads and the non-pad regions.

Implementations of the apparatus may include one or more of following features. The bonding-pad regions on the lower surface of the magnetically permeable core comprise a plurality of square bonding pads arranged in a two-dimensional array.

Implementations of the apparatus may include one or more of following features. The magnetically permeable core comprises at least two magnetically permeable core sections; the windings are arranged between the magnetically permeable core sections within grooves formed in the selected magnetically permeable core section or selected magnetically permeable core sections.

Implementations of the apparatus may include one or more of following features. Each of the windings is provided with three vertical sections and two lateral sections which are alternately connected; the distance between the two lateral sections is twice the distance between the upper one of the lateral sections and the upper surface of the magnetically permeable core; and the distance between the two lateral sections is twice the distance between the lower one of the lateral sections and the lower surface of the magnetically permeable core.

Implementations of the apparatus may include one or more of following features. Two windings and three magnetically permeable core sections are provided; the magnetically permeable core sections comprises a first magnetically permeable core section, a second magnetically permeable core section and a third magnetically permeable core section, wherein the third magnetically permeable core section are arranged between the first and second magnetically permeable core sections; and

wherein the windings are respectively arranged between the magnetically permeable core sections; either of the windings are arranged within a groove formed on a surface of the respective one of the first and second magnetically permeable core sections.

Implementations of the apparatus may include one or more of following features. The first and second magnetically permeable core sections have the same width, and the width of the third magnetically permeable core section is greater than the width of the first magnetically permeable core section and less than twice the width of the first magnetically permeable core section.

Implementations of the apparatus may include one or more of following features. The first and second magnetically permeable core sections have the same width, and the width of the first magnetically permeable core section is greater than the width of the third magnetically permeable core section.

Implementations of the apparatus may include one or more of following features. The first and second magnetically permeable core sections are made of a material with high saturation magnetization, and the third magnetically permeable core section is made of a material with high magnetic permeability.

In general, another aspect features a method, comprising:
providing a set of preformed metal pieces comprising input pin pieces and windings;
manufacturing a semi-finished magnetically permeable core;
assembling the input pin pieces, the windings and the semi-finished magnetically permeable core, and then carrying out a hot-pressing process and annealing to form an integrated core assembly;
coating at least one outer surface of the integrated core assembly with an insulation layer;
forming openings on the insulation layer, wherein a method comprising laser engraving and/or chemical etching is used; and
forming signal pins in selected ones of the openings by means of a metallization process.

Implementations of the method may include one or more of following features. The preformed metal pieces are respectively provided with bonding-pad regions and non-pad regions, and the bonding-pad regions are exposed at openings which are not selected for forming the signal pins.

Implementations of the method may include one or more of following features. The input pin pieces comprise a ground pin and an input voltage pin, and at least a part of the non-pad region of the input voltage pin is overlapped with and insulated from the ground pin.

Implementations of the method may include one or more of following features. Input pin pieces comprise a ground pin, an input voltage pin and a shielding layer, at least a part of the non-pad region of the input voltage pin is overlapped with and insulated from the shielding layer.

Implementations of the method may include one or more of following features. Further comprising: forming a shielding layer on the outer side of the integrated core assembly, wherein at least a part of the shielding layer is overlapped with and insulated from the input pin pieces;
wherein the process of forming the shielding layer is carried out after the process of forming the openings.

Implementations of the method may include one or more of following features. Selected one or selected ones of the openings are in a groove-with-via shape comprising groove regions which do not penetrate the insulation layer and via regions which penetrate the insulation layer; the selected DC pin piece or selected input pin pieces are exposed a the via region; and
wherein the shielding layer is formed within the groove-with-via shaped openings by means of the metallization process; the shielding layer is electrically connected to the selected DC pin piece or selected input pin pieces through the via regions.

Implementations of the method may include one or more of following features.

Selected one or selected ones of the openings further penetrates the input pin pieces and divided the input pin pieces into a plurality of DC voltage pins, and the DC voltage pins comprise input voltage pins and ground pins.

In general, another aspect features power module, comprising

A magnetic apparatus comprising preformed metal pieces, a magnetically permeable core and signal pins; and

IPM units comprising power semiconductor devices;
wherein the preformed metal pieces comprise DC voltage pins and windings;
wherein the magnetically permeable core is arranged around at least a part of the windings, and the DC voltage pins are integrated with the magnetically permeable core;
wherein the signal pins are arranged on outer surfaces of the magnetically permeable core through a metallization process;
wherein the preformed metal pieces and the signal pins are respectively provided with bonding-pad regions and non-pad regions, and the bonding-pad regions on either of a upper surface and a lower surface of the magnetically permeable core are coplanar; and
wherein the IPM units are arranged on the upper surface of the magnetically permeable core.

Implementations of the power module may include one or more of following features. Further comprising: a wiring board and output capacitors;
wherein the wiring board is arranged at a lower side of the magnetically permeable core;
wherein the output capacitors are arranged on an upper surface of the wiring board or configured within the wiring board; and
wherein the wiring board and the IPM units are electrically connected with the selected preformed metal pieces respectively.

Implementations of the power module may include one or more of following features. The output capacitors are embedded in the wiring board; and
wherein the output capacitors are formed by providing at least two wiring layers in the wiring board and arranging at least one insulating layer with a high dielectric constant between the wiring layers.

Implementations of the power module may include one or more of following features. Further comprising a controller; wherein the controller is arranged on a surface of the magnetic apparatus, and the controller is electrically connected with the signal pins.

Implementations of the power module may include one or more of following features. Further comprising a plurality of input capacitors;
wherein the DC voltage pins comprise input voltage pins and ground pins;
wherein one end of each of the input capacitors is electrically connected with the selected input voltage pin or selected input voltage pins, and another end of each of the input capacitors is electrically connected with the selected ground pin or selected ground pins; and
wherein at least one of the input capacitors is located on a lower surface of the IPM units.

### DESCRIPTION OF DRAWINGS

FIGS. 1A to 1D are schematic diagrams of a power module in the prior art;

FIGS. 2A to 2G are schematic diagrams according to one or more embodiments;

FIGS. 3A to 3G are schematic diagrams according to one or more embodiments;

FIGS. 4A to 4E are schematic diagrams according to one or more embodiments;

FIG. 5 is a schematic diagram according to one or more embodiments;

FIGS. 6A to 6B are schematic diagrams according to one or more embodiments;

FIGS. 7A to 7F are schematic diagrams according to one or more embodiments;

FIGS. 8A to 8C are schematic diagrams according to one or more embodiments;

FIGS. 9A to 9C are schematic diagrams according to one or more embodiments.

### DETAILED DESCRIPTION

The present application discloses various embodiments or examples of implementing the thematic technological schemes mentioned. To simplify the disclosure, specific instances of each element and arrangement are described below. However, these are merely examples and do not limit the scope of protection of this invention. For instance, a first feature recorded subsequently in the specification formed above or on top of a second feature may include an embodiment where the first and second features are formed through direct contact, or it may include an embodiment where additional features are formed between the first and second features, allowing the first and second features not to be directly connected. Additionally, these disclosures may repeat reference numerals and/or letters in different examples. This repetition is for brevity and clarity and does not imply a relationship between the discussed embodiments and/or structures. Furthermore, when a first element is described as being connected or combined with a second element, this includes embodiments where the first and second elements are directly connected or combined with each other, as well as embodiments where one or more intervening elements are introduced to indirectly connect or combine the first and second elements.

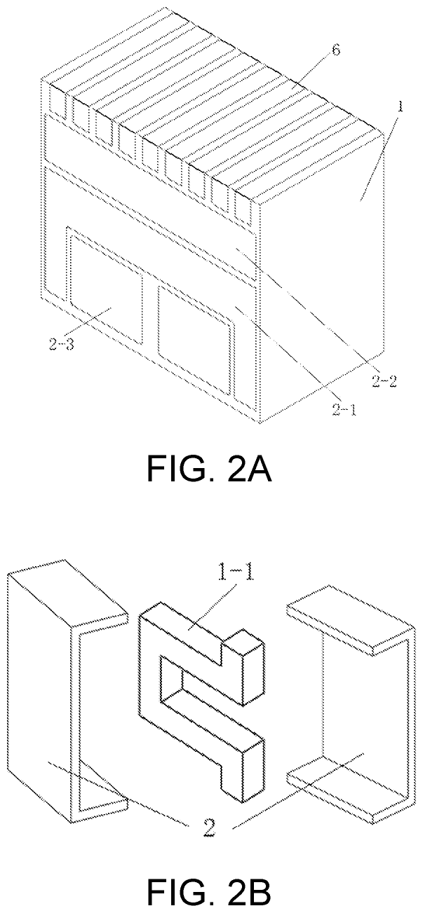

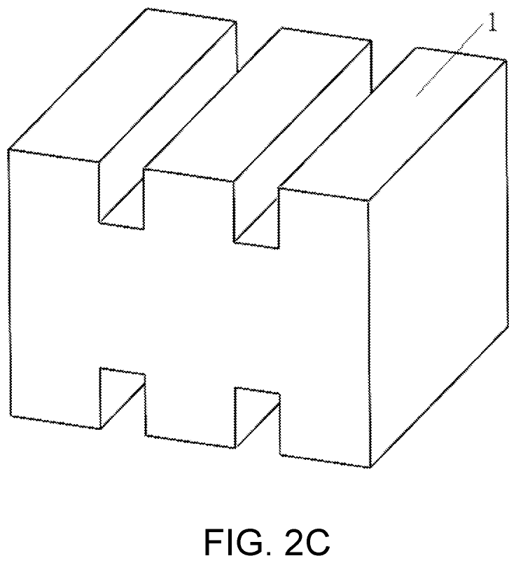

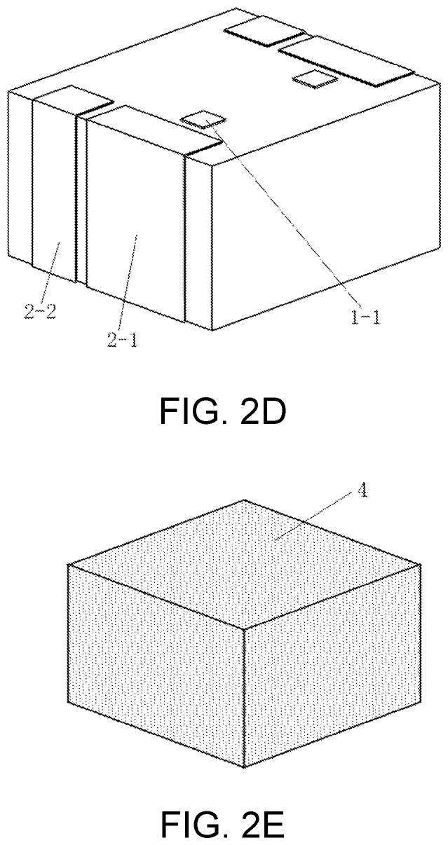

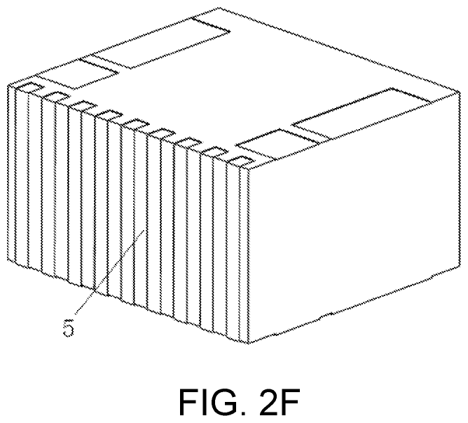

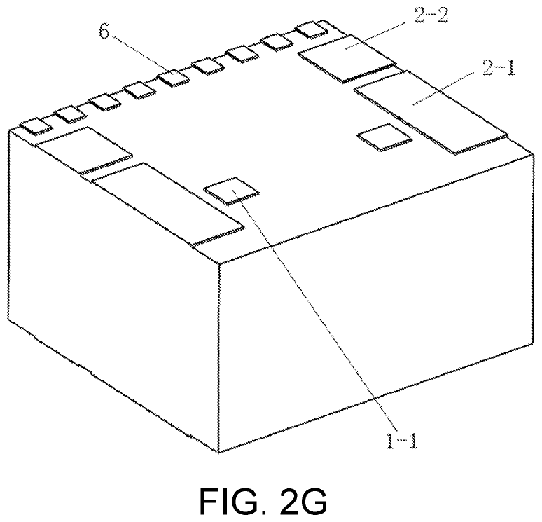

In some embodiments, the structure of the magnetic apparatus comprises preformed metal pieces, a magnetically permeable core 1 and a signal pin 6; The preformed metal pieces include a input voltage pin 2-1, a ground pin 2-2 and two windings 1-1; the magnetically permeable core 1 is arranged around at least a part of the windings 1-1; the input voltage pin 2-1 and the ground pin 2-2 are both integrated with the magnetically permeable core 1; the signal pins 6 are arranged on the outer surface of the magnetically permeable core 1 through a metallization process; the preformed metal pieces and the signal pins 6 are respectively provided with bonding-pad regions and non-pad regions; and the bonding-pad regions are coplanar on the upper/lower surface of the magnetcially permeable core 1. The bonding-pad region of the input voltage pin 2-1 is electrically connected with the non-pad region on the two opposite sides (i.e., the left-back and right-front sides in FIG. 2A) of the magnetically permeable core 1, so that the input voltage pin 2-1 is formed in entirety; the ground pin 2-2 is also formed in entirety, and the non-pad regions of the input voltage pin 2-1 and the ground pin 2-2 are not exposed.

FIG. 2G shows a structure of another magnetic apparatus according to some embodiments, wherein two input voltage pins 2-1 and two ground pins 2-2 are provided, as shown in FIG. 2A.

FIGS. 2B-2G show a manufacturing method of the magnetic apparatus of FIG. 2G, comprising:

Step 1: providing a set of preformed metal pieces, including an input voltage pin 2-1, a ground pin 2-2 and windings 1-1, as shown in FIG. 2B;

Step 2: manufacturing a semi-finished magnetically permeable core 1, as shown in FIG. 2C;

Step 3: assembling the input voltage pin 2-1, the ground pin 2-2, the winding 1-1 and the semi-finished magnetically permeable core 1, and then carrying out a hot pressing to form an integrated core assembly (in some embodiments, a high-temperature annealing is subsequently carried out), as shown in FIG. 2D;

Step 4: coating all outer surfaces of the integrated core assembly with an insulation layer 4, as shown in FIG. 2E;

Step 5: forming openings 5 on the insulation layer 4, wherein a method of laser engraving is used, and the bonding-pad regions are exposed through the openings 5, as shown in FIG. 2F; a part of the openings 5 are formed on the side surface of the integrated core assembly;

Step 6: carrying out a metallization process on the openings 5, so that bonding pads are formed on the upper and lower surface and signal pins 6 are formed on the side surface, as shown in FIG. 2G.

The input voltage pin 2-1, the ground pin 2-2 and the winding 1-1 are pre-formed and assembled. Compared with the prior arts in which pins are bent along the edge of the inductor, the reliability risk caused by the damage to the inductor 15 is reduced, and the input voltage pin 2-1, the ground pin 2-2 and the winding 1-1 may be formed by stamping through a mold, so that it is suitable for the case with a relatively thin inductor 15, and the limitation caused by the bending process is also avoided.

In the Step 3, the input voltage pin 2-1, the ground pin 2-2, the winding 1-1 and the semi-finished magnetically permeable core 1 are integrally formed through a hot pressing process, so that the space utilization rate of the magnetically permeable core is maximized, batch production can be carried out in one mold with multiple holes, the compactness and uniformity of particles in the magnetically permeable core can be improved through high-temperature annealing treatment, and meanwhile the internal stress is released; the non-pad regions of the input voltage pin 2-1 and the ground pin 2-2 may be arranged on the outer surface of the magnetically permeable core 1, or may also be embedded in the magnetically permeable core 1 with a distance of no more than 1 mm to the outer surface of the magnetically permeable core 1, so that the non-pad regions of the input voltage pin 2-1 and the ground pin 2-2 is directly covered by the magnetically permeable core 1 and is insulated and separated from the outside.

In the Step 6, the signal pins 6 are formed through a metallization process on the surface of the magnetically permeable core 1, so that the signal pins 6 are provided very thin due to the solidity of the core. Therefore, the occupied space of the signal pins 6 is minimized, the utilization of the magnetically permeable core 1 is improved, and the magnetic loss is reduced.

In some embodiments, the metallization process in Step 6 is roll-plating of Cu, Ni or Sn, preventing the copper foil from being oxidized, and improving the welding quality.

The bonding-pad region on the upper surface and the lower surface of the magnetic apparatus is formed by firstly spraying the insulation layer 4, secondly laser engraving to form the openings 5 and then electroplating. The bonding pad formed by engraving on the same plane is high in precision, such as +/−0.05 mm. Compared with the bonding pad tolerance (+/−0.2 mm) formed by bending process in the prior art, the welding quality can be effectively improved, and the risk of short circuit is reduced. The shape of the preformed metal pieces is determined by the mold, and the flatness tolerance of the mold can be controlled within +/−25 microns, so that the bonding-pad regions of the preformed metal pieces and the signal pins 6 on the same surface may get a good coplanarity, and the risk of open circuit caused by the non-coplanarity is effectively reduced.

The aforementioned hot-pressing forming process, surface spraying, laser engraving and the roll-plating process are all suitable for batch production. Compared with the inductor-pin assembly which need to bend the outer wiring one by one in the prior art, the process has the feasibility for batch production, and the cost is correspondingly reduced.

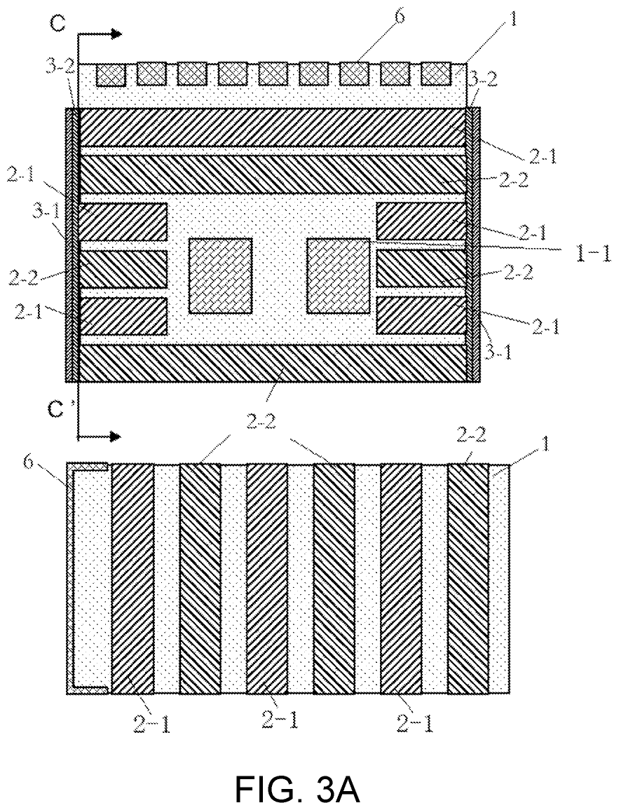

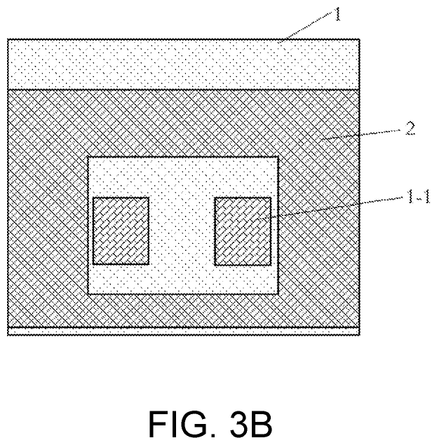

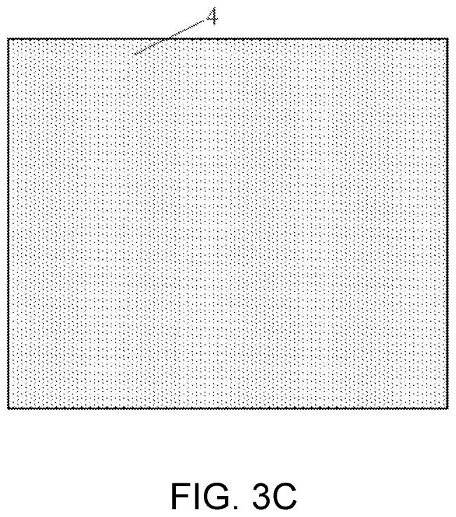

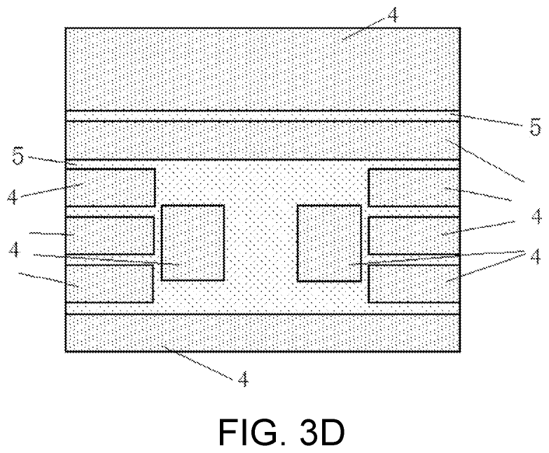

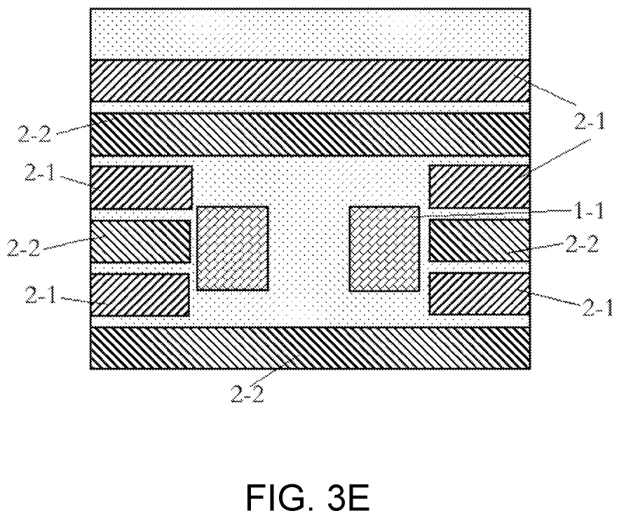

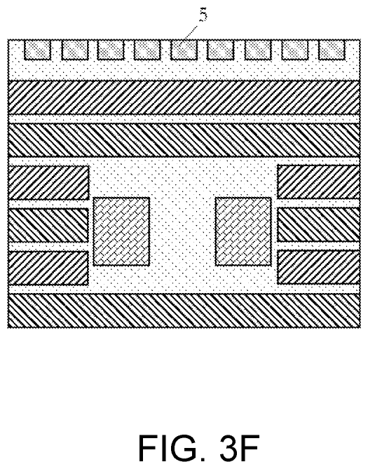

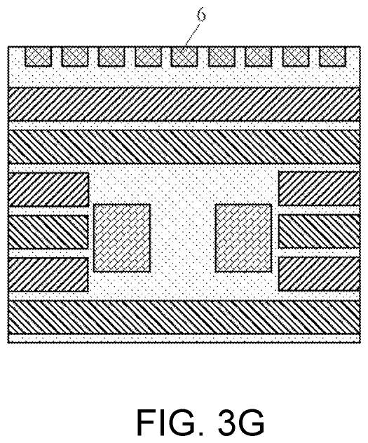

In some embodiments, as shown in FIG. 3A (the upper graph of FIG. 3A is a top view, and the lower graph is a C-C′ cross-sectional view), the magnetic apparatus comprises a magnetically permeable core 1, input voltage pins 2-1, ground pins 2-2, shielding layers 3-1, insulating layers 3-2 and signal pins 6. As shown in FIG. 3A, the input voltage pins 2-1, the ground pins 2-2, the shielding layers 3-1 and the insulating layers 3-2 are arranged on the surfaces of the magnetically permeable core 1. The input voltage pins 2-1 and the ground pins 2-2 are arranged across two opposite side surfaces of the magnetically permeable core 1, the insulating layer 3-2 and the shielding layer 3-1 are arranged on the side surfaces corresponding to the input voltage pins 2-1 and the ground pins 2-2, and the bonding-pad regions are all arranged on the upper and lower surfaces of the magnetically permeable core 1.

In some embodiments, the input voltage pin 2-1 and the ground pin 2-2 are arranged in an alternating arrangement, that is, the loops of the plurality of input voltage pins 2-1 and ground pin 2-2 are connected in parallel, so that the parasitic inductance is reduced. The power pin preform is formed by integrally hot-pressing a plurality of preformed metal and a large inductor 15 through a hot-pressing process. The spacing between the input voltage pin 2-1 and the ground pin 2-2 of the present embodiment is generated by chemical etching, so that the distance between the input voltage pin 2-1 and the ground pin 2-2 can be set to be smaller.

FIGS. 3B-3G show a method for manufacturing a magnetic apparatus of some embodiments (FIGS. 3B-3G are both top views), comprising:

Step 1: providing a set of preformed metal pieces, including input pin pieces and windings 1-1; a copper layer 2 is provided as the input pin pieces and is divided into individual pins in the following step 5;

Step 2: manufacturing a semi-finished magnetically permeable core 1;

Step 3: assembling the copper layer 2, the winding 1-1 and the semi-finished magnetically permeable core 1, and then carrying out hot pressing to form a semi-finished integrated core assembly, as shown in FIG. 3B;

Step 4: coating all outer surfaces of the semi-finished integrated core assembly with an insulation layer 4, as shown in FIG. 3C;

Step 5: comprising steps 5-1 to 5-3;

Step 5-1: forming a part of the openings 5 on the insulation layer 4, so that a part of the copper layer 2 is exposed, as shown in FIG. 3D;

Step 5-2: further carrying out chemical etching on the exposed copper layer 2 at the openings 5, dividing the copper layer 2 into a plurality of DC voltage pins, wherein the DC voltage pins comprise input voltage pins 2-1 and ground pins 2-2, and then removing the insulation layers 4 on the bonding-pad regions of the input voltage pins 2-1 and the ground pins 2-2, as shown in FIG. 3E;

Step 5-3: forming another part of the openings 5 (including vertical grooves on a side surface of the integrated core assembly and adjacent regions on the upper and lower surfaces) on the insulation layer 4 through laser engraving, as shown in FIG. 3F;

Step 6: performing metallization process processing on the opening 5, as shown in FIG. 3G; signal pins 6 are also formed in the openings 5 by metallization.

Step 7: shielding layers 3-1 and insulating layers 3-2 are further disposed on the integrated core assembly (the insulating layer 3-2 is also a glue layer), as shown in FIG. 3A.

In some embodiments, Step 4 may be carried out multiple times between the sub-steps in Step 5.

In some embodiments, according to actual requirements, the copper layer 2 can be milled in a machining mode, then the insulation layer 4 is coated on all the surfaces, the openings 5 for forming the signal pins 6 are exposed through laser engraving, and finally the signal pins 6 are formed through a metallization process.

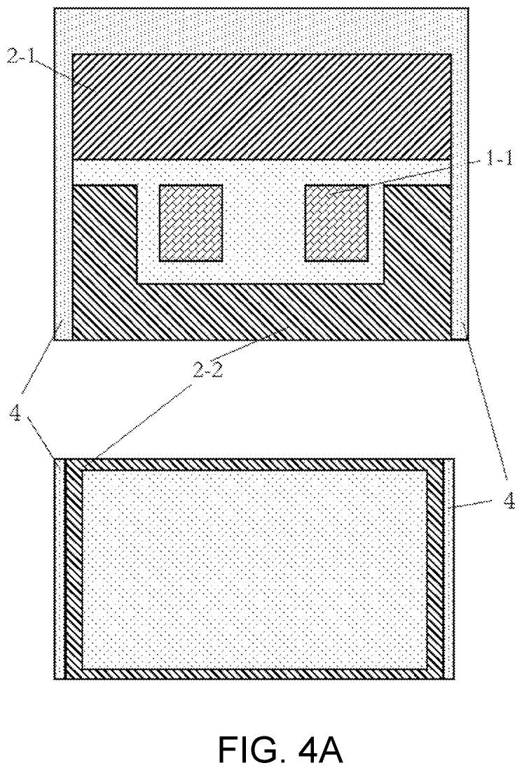

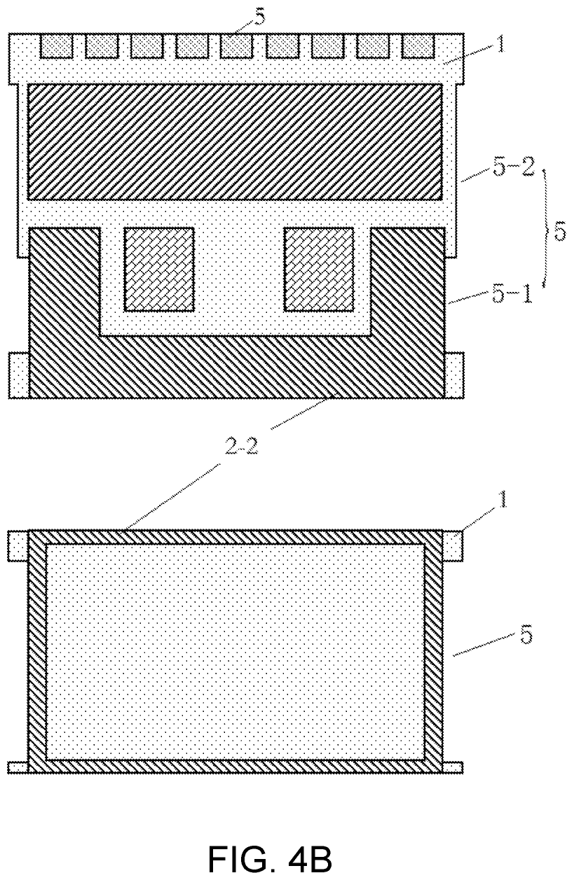

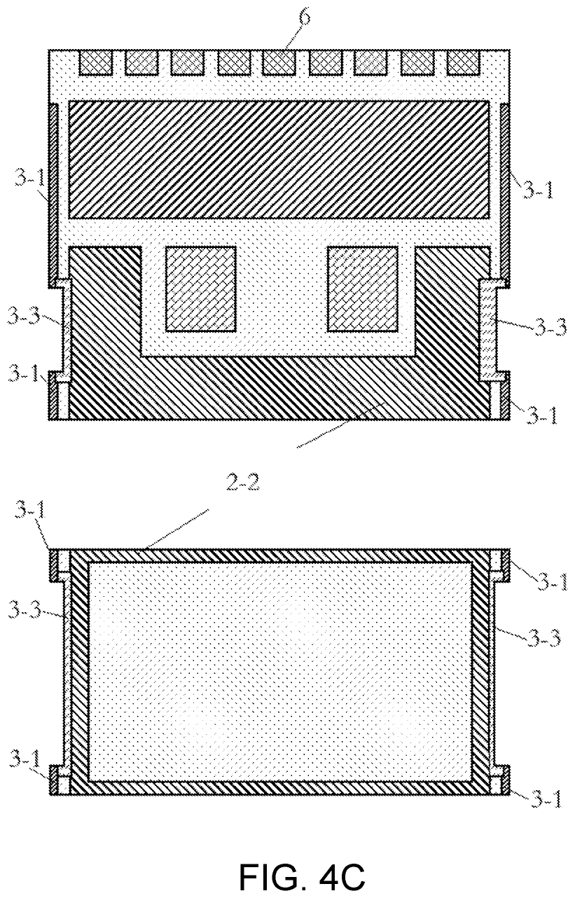

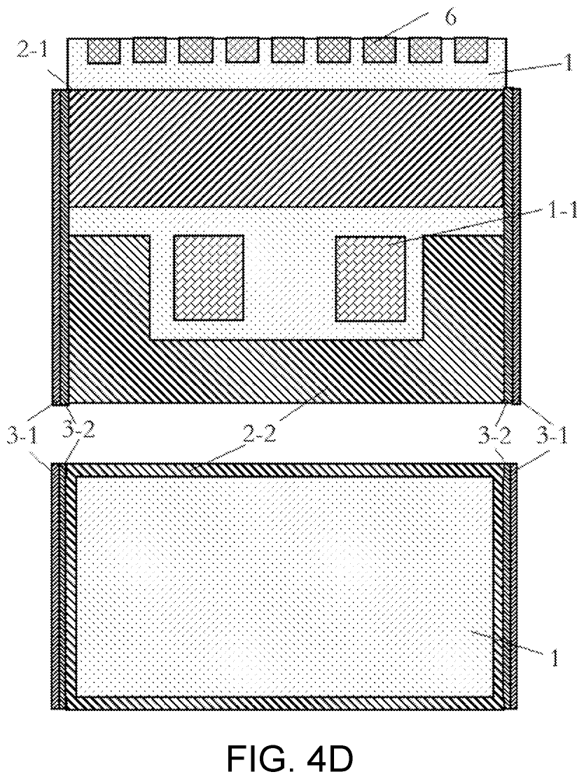

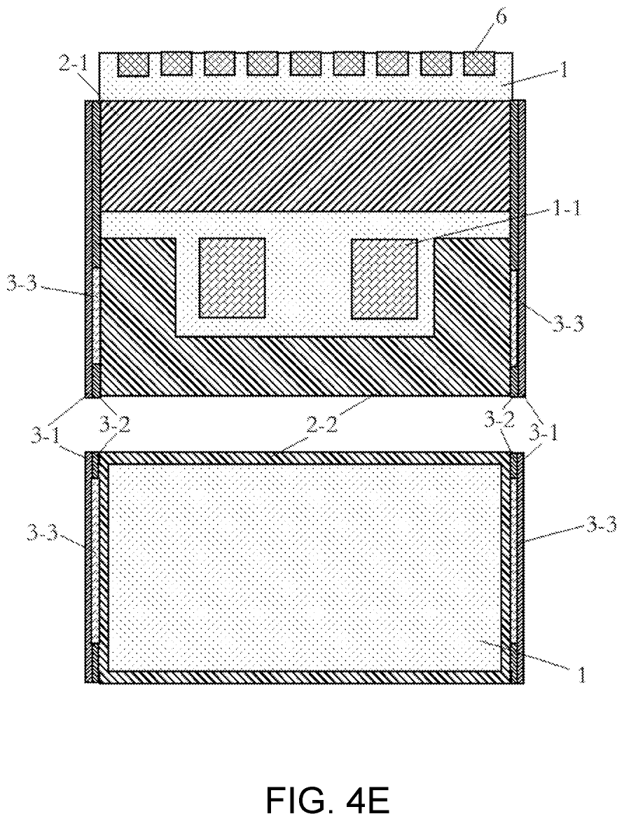

In some embodiments, as shown in FIGS. 4A to 4C, (the upper portions of FIGS. 4A-4C are top views, and the lower portions of FIGS. 4A-4C are front views with ground pins 2-2 being front faces):

Step 1: providing a set of preformed metal pieces, including an input voltage pin 2-1, a ground pin 2-2 and windings 1-1;

Step 2: manufacturing a semi-finished magnetically permeable core 1;

Step 3: assembling the input voltage pin 2-1, the ground pin 2-2, the windings 1-1 and the semi-finished magnetically permeable core 1, and then carrying out hot pressing to form an semi-finished integrated core assembly, as shown in FIG. 4A;

Step 4: coating an insulation layer 4 on the side surfaces and a part of the upper and lower surfaces of the semi-finished integrated core assembly;

Step 5: carrying out laser engraving: the ground pin 2-2 is exposed on the side surfaces to form contact regions 5-1; the insulation layer 4 covering the input voltage pin 2-1 on the side surfaces is semi-etched to form shielding regions 5-2 (i.e., a thinner insulation layer 4 is reserved); the contact region 5-1 and the shielding region 5-2 on one side form a continuous opening 5; and another part of the openings 5 are formed at the position corresponding to the signal pins, as shown in FIG. 4B;

Step 6: forming signal pins 6 in the openings 5 by means of a metallization process;

Step 7: forming contact layers 3-3 and shielding layers 3-1 in the openings 5 by means of a metallization process, as shown in FIG. 4C.

The shielding layers 3-1 in the aforementioned method are directly disposed on the side surfaces of the magnetically permeable core 1 and are electrically connected to the ground pin 2-2 through the contact layers 3-3; the shielding layers 3-1 and the signal pins 6 are directly formed on the side surfaces of the magnetically permeable core 1 without welding and the process is simplified.

In some embodiments, the shielding layers 3-1, the insulating layers 3-2 and the magnetically permeable core 1 are fixedly connected at the assembling as shown in FIG. 4D (the upper graph is a top view and the lower graph is the front view taking the ground pin 2-2 as the front side) according to actual requirements, and the insulating layer 3-2 is located between the shielding layer 3-1 and the magnetically permeable core 1.

In some embodiments, as shown in FIG. 4E (the upper graph is a top view, and the lower graph is a front view taking the ground pin 2-2 as the front face), electrical connections between the ground pin 2-2 and the shielding layers 3-1 are further formed on the basis of FIG. 4D, that is, contact layers 3-3 are arranged between the ground pin 2-2 and the shielding layers 3-1 across the insulating layers 3-2 (which may also be welding layers) , which may further reduce the parasitic inductance of the input current loop.

In some embodiments, the shielding layer 3-1 is formed by screen printing of silver paste.

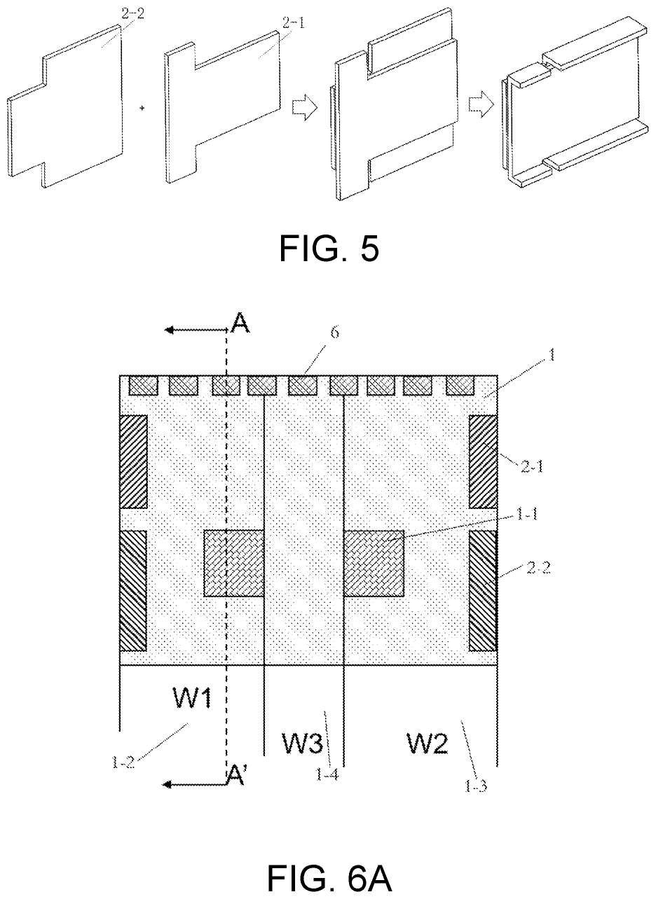

In some embodiments, as shown in FIG. 5, the input voltage pin 2-1 and the ground pin 2-2 are in a stacked arrangement, so that the ground pin 2-2 functions as the shielding layer, and therefore, the steps of chemical etching, milling or forming openings used for forming an additional shielding layer are not needed.

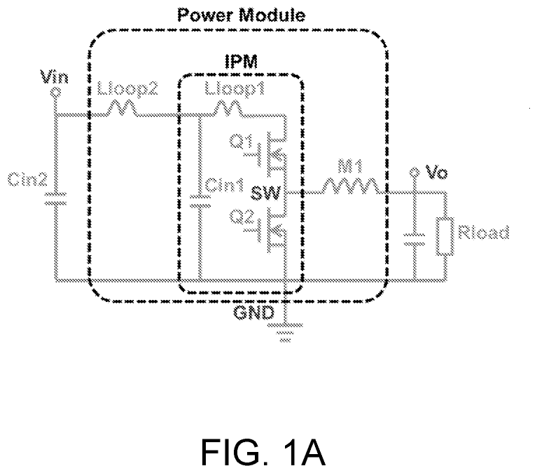

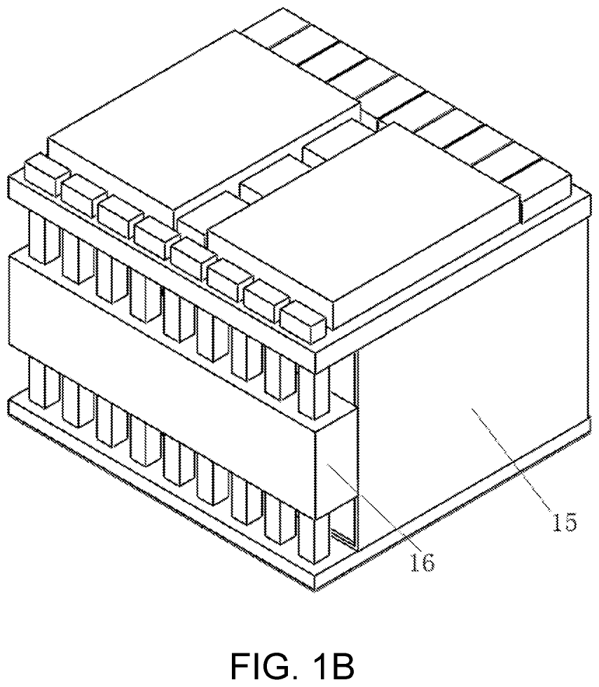

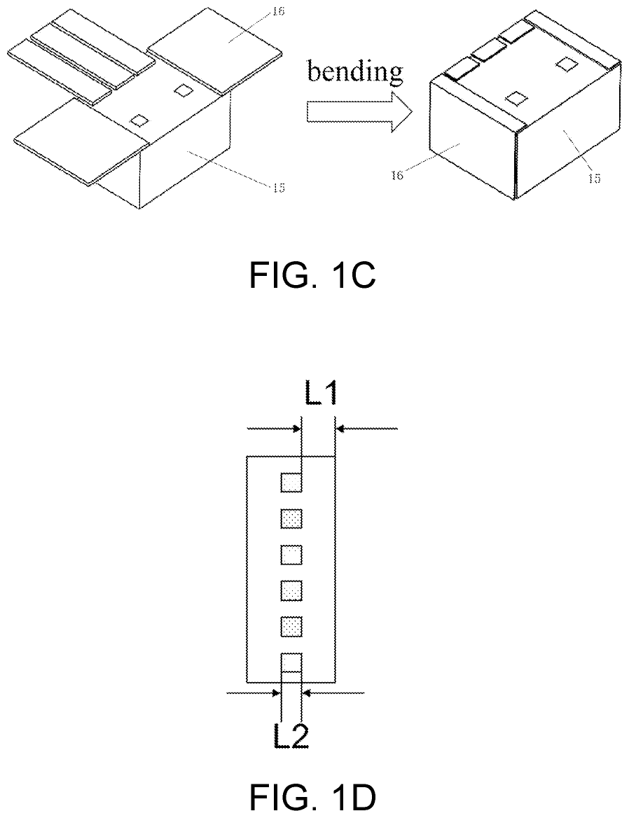

The input voltage pin 2-1 and a ground pin 2-2 are overlapped and placed together, and the input voltage pin 2-1 and the ground pin 2-2 are bonded together through a insulating connecting layer (not shown in the Fig.). The thickness of the connecting layer is very low, such as 20-50 μm. Therefore, the area of the input current loop formed by the input voltage pin 2-1 and the ground pin 2-2 is obviously reduced (Loop 2 shown in FIG. 1A), so that the parasitic inductance is effectively reduced. A bending is then carried out.

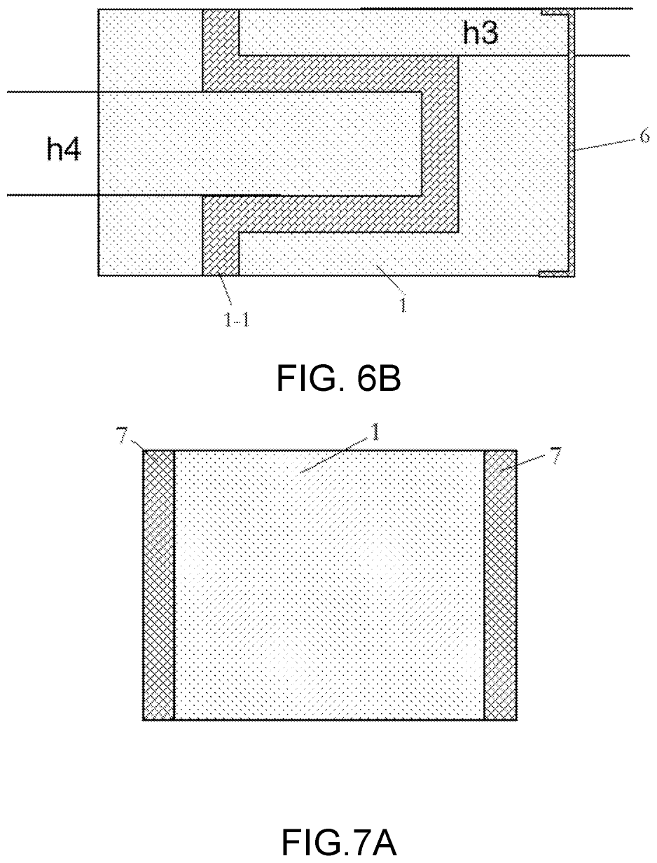

In some embodiments, as shown in FIGS. 6A to 6B (FIG. 6A is a top view, and FIG. 6B is a A-A ‘cross-sectional view), the magnetically permeable core 1 comprises two windings 1-1, a first magnetically permeable core section 1-2, a second magnetically permeable core section 1-3, and a third magnetically permeable core section 1-4.

The widths of the first magnetically permeable core section 1-2, the second magnetically permeable core section 1-3, and the third magnetically permeable core section 1-4 are respectively W1, W2 and W3, and W1=W2>W3. The magnetic coupling coefficient of the two windings is relatively high and it is suitable for the case in which the two circuit paths of the windings output the electric power in parallel. In some case to an extreme, W3 may be reduce to zero for the highest coupling.

In some embodiments, the widths of the first magnetically permeable core section 1-2 and the second magnetically permeable core section 1-3 are the same, and the width of the third magnetically permeable core section 1-4 is greater than the width of the first magnetically permeable core section 1-2 and less than twice of that, that is, W1=W2, W1<W3<2W1. The magnetic coupling coefficient of the two windings is relatively low and it is suitable for the case in which the two circuit paths of the windings provide individual outputs.

As shown in FIG. 6B, the windings 1-1 includes three vertical sections and two lateral sections which are alternately connected; the two lateral sections and one vertical section form a U-shaped part; and the other two vertical sections are additional lead-outs respectively leading to the upper and the lower surfaces of the magnetically permeable core. The space utilization of the magnetically permeable core from the thickness direction is maximized with the disposition of U-shaped windings. H4 is the distance between the two lateral sections of the U-shaped part, H3 is the distance between the lateral section and the outer surface of the magnetically permeable core. H4 is configured approximately equal to two times of H3, so that the magnetic field distribution is relatively uniform, and the magnetic loss is reduced.

In some embodiments, the first magnetically permeable core section 1-2 and the second magnetically permeable core section 1-3 are made of a material with high saturation magnetization, and the third magnetically permeable core section 1-4 is made of a material with high magnetic permeability. For example, the third magnetically permeable core section 1-4 is ferrite, the first magnetically permeable core section 1-2 and the second magnetically permeable core section 1-3 are iron powder core sections. The iron powder has relatively excellent saturation magnetization, and the ferrite has relatively excellent magnetic permeability, so that the coupling coefficient is minimized for forming a non-coupling inductor. The aforementioned combination of several core sections with selected relative size and selected materials is suitable for various requirements of inductance characteristics in multiple applications.

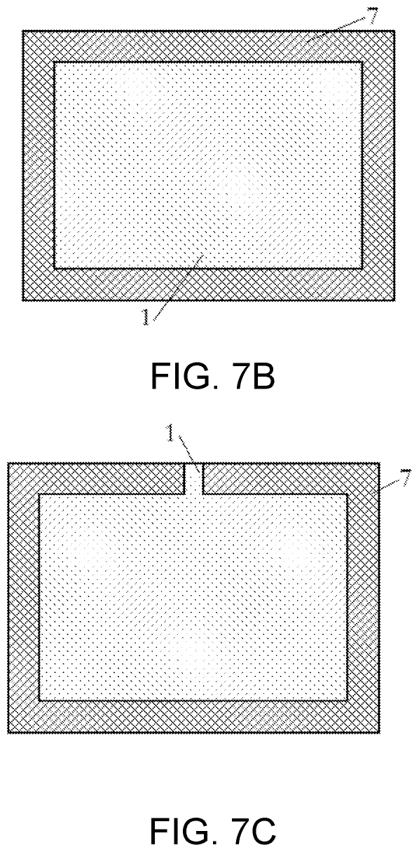

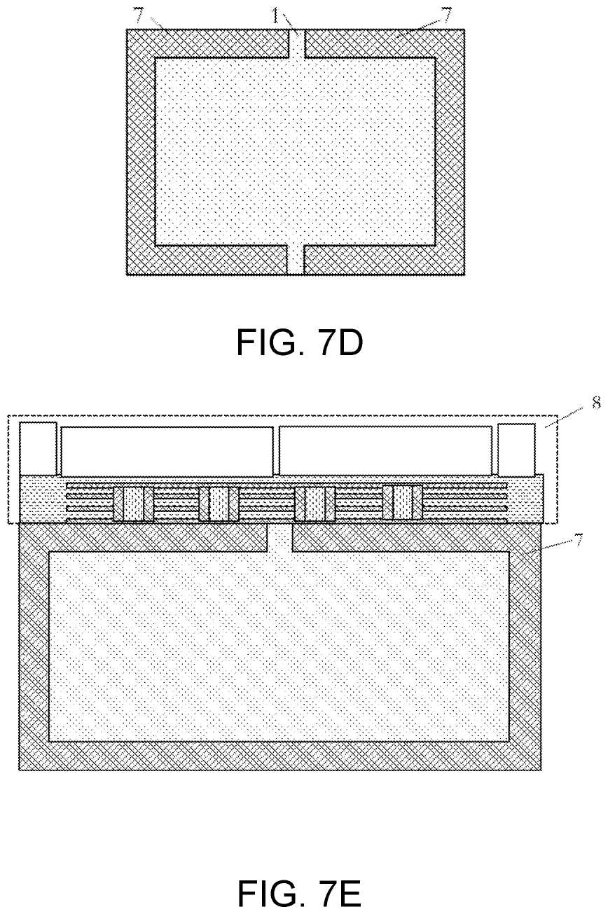

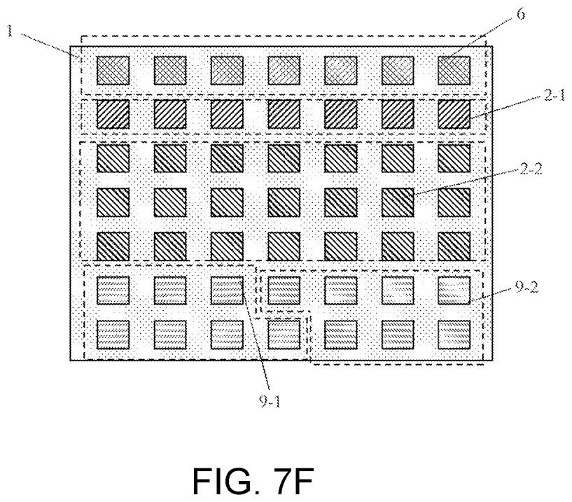

In some embodiments, as shown in FIGS. 7A to 7D, the non-pad regions of the input pin pieces are arranged on at least two side surfaces of the magnetically permeable core 1, the bonding-pad region comprises thick-layer lateral-wiring regions 7 and bonding pads, and the thick-layer lateral-wiring regions 7 are electrically connected with the bonding pads and the non-pad regions. FIGS. 7A to FIG. 7D respectively show the cases that the thick-layer lateral-wiring regions 7 on the upper and lower surfaces fully extend from one edge to another or not.

FIG. 7E is a schematic diagram of IPM units 8 assembled above the magnetic apparatus of FIG. 7C. Most of the IPM units 8 are in QFN (Quad Flat No-lead) encapsulations. The pins of the IPM units 8 are located under the encapsulation body, while the input pin pieces transmit input current from the side surfaces of the magnetically permeable core 1, so lateral DC current transmission is certainly needed between the IPM units 8 and the side edges of the upper surface of the magnetically permeable core 1. On one hand, lateral current may be transmitted through internal wiring, and on the other hand, power wiring integrated with the inductor may be used. Due to the fact that the thickness of the internal wiring is limited by the producing process, and the width of lines and the distance between lines are increased along with the increase of the thickness of the wiring, the size of the bonding pads and the distance between the bonding pads may not meet the specification of the IPM units 8 in the case of a high internal wiring thickness. Therefore, integrating lateral power wiring with the inductor on its upper surface is a good choice. The copper foil for forming the input pin pieces may be specified according to the current requirement, and due to the fact that the input pin pieces is pre-formed, no technical difficulty is brought to a subsequent hot-pressing integrating process, so that the impedance of the lateral current transmission may be provided very low by means of providing thick-layer lateral-wiring regions 7 in the pre-formed input pin pieces.

A conventional requirement of the bonding pad layout of the power module according to practical applications is shown in FIG. 7F. The bonding pads are a plurality of squares arranged in a two-dimensional array, and due to the fact that signal pins are configured to form a pin header and power pins are bent along the side edges of the inductor in the prior art, bonding pads formed at the bottom of the inductor do not meet such requirement. According to the aforementioned embodiments, the input pin pieces is integrally hot-pressed and formed through the preformed copper foil, the laser engraving is carried out after the surface coating is carried out, and the bonding pads and the signal pins 6 are respectively formed through a metallization process after openings 5 are made, so that the layout of the bonding pads may be easily defined by the laser engraving to meet the specifications and requirements of practical applications. More space in height direction is utilized for the magnetically permeable core 1, which means its volume is increased the its loss is reduced.

It should be noted that if the input voltage pin 2-1 and the ground pin 2-2 are alternately arranged according to some of the aforementioned embodiments, the input voltage pin 2-1 and the ground pin 2-2 do not directly form the layout that a plurality of square bonding pads are arranged in the two-dimensional array shown in FIG. 7F, so that a rewiring needs to be carried out. The rewiring is carried out on the basis of FIG. 2E, and includes insulation coating, laser engraving, seed layer sputtering, electroplating and etching. One series of the processes is carried out for forming one rewiring layer and if the number of required rewiring layers is more than one, the series of the processes may be repeatedly carried out.

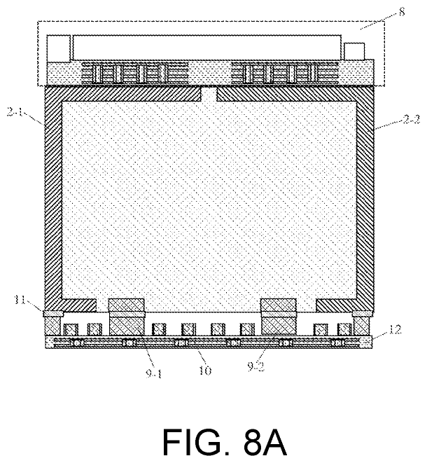

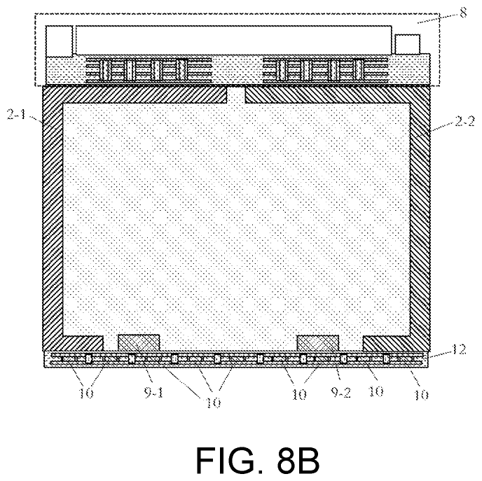

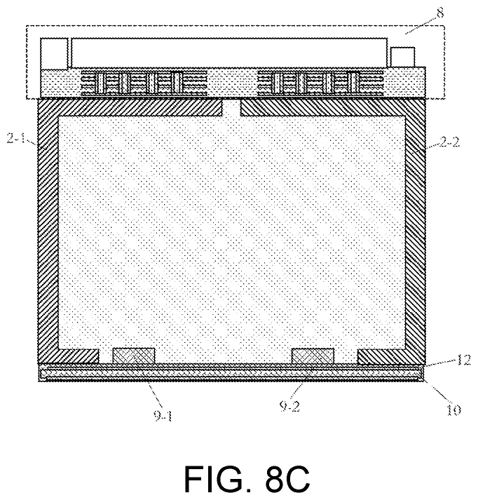

FIG. 8A shows a power module using the magnetic apparatus in some embodiments. The power module further comprises IPM units 8, wherein the IPM units 8 are arranged on the upper surface of the magnetically permeable core 1; a wiring board 12 is arranged below the magnetically permeable core 1; output capacitors 10 are arranged on the upper surface of the wiring board 12 or embedded in the wiring board 12; and the wiring board 12 and the IPM units 8 are electrically connected with the corresponding side of the ground pin 2-2 and the input voltage pin 2-1 respectively(through solder 11); the output capacitors 10 are arranged on the wiring board 12. The wiring board 12 further comprises a first output voltage pin 9-1 and a second output voltage pin 9-2, and the first output voltage pin 9-1 and the second output voltage pin 9-2 are used for the electrically connecting between the magnetic apparatus and the wiring board 12. The output capacitors 10 are integrated into the power module, so that the space on the system board is saved, the distance between the power module and the load is shortened, the power module is arranged close to the load, the transmission impedance between the power module and the load is minimized, and the dynamic characteristic performance is optimized.

In some embodiments, as shown in FIG. 8B, the output capacitors 10 are embedded in the wiring board 12, and the magnetically permeable core 1 is electrically connected to the wiring board 12, so that the height of the power module can be further reduced.

In some embodiments, as shown in FIG. 8C, the wiring board 12 is provided with at least two wiring layers, and at least an insulating layer with a high dielectric constant is arranged between the wiring layers. The output capacitors 10 are therein formed. The space utilization is high in such arrangement, and the capacitance value is effectively improved.

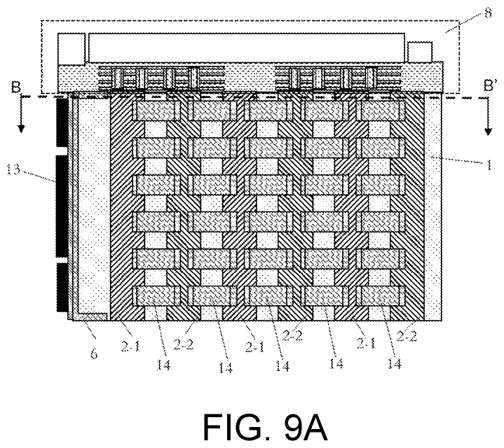

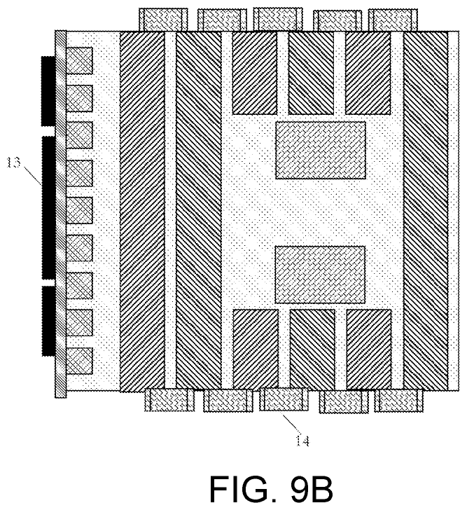

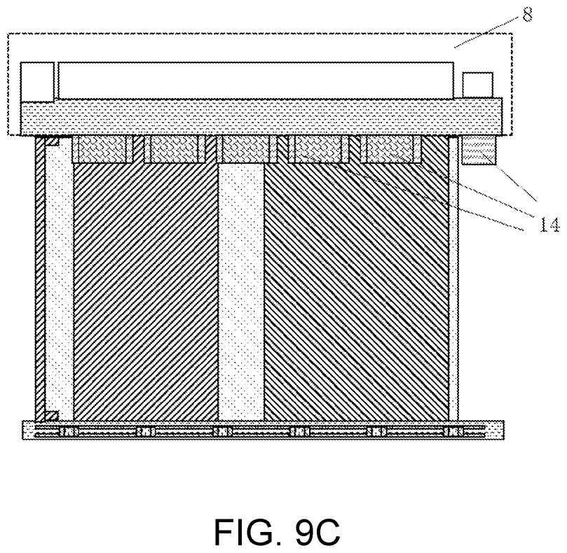

In some embodiments, a plurality of square bonding pads arranged in a two-dimensional array is provided at the bottom of the magnetic apparatus as the substitution for a wiring board, and on the other hand, the magnetic apparatus further comprises a controller 13 and a plurality of input capacitors 14, and the controller 13 is arranged on one surface of the magnetically permeable core 1; and the two ends of each of the input capacitors 14 are electrically connected with the ground pins 2-2 and the input voltage pins 2-1 respectively. FIGS. 9A-9B show the structure of the power module (FIG. 9A is a front view, and FIG. 9B is a cross-sectional top view of the B-B′ in FIG. 9A).

The controller 13 is integrated in the power module, so that the control circuit loop is shortened, and the transmission loss is minimized; the input current loop area (Loop 2) of the power module shown in FIG. 1A is also lessened, the parasitic inductance is thus lessened, and the loss is minimized.

In some embodiments, as shown in FIG. 9C, some of the input capacitors 14 are arranged on the lower surface of the IPM units 8, and the effect of reducing the parasitic inductance of the loop is thus achieved. After the magnetic apparatus is machined, the magnetic apparatus is surface mounted to the lower surface bonding pad of the IPM units 8 together with the input capacitors 14.

The beneficial effects of the invention are that:
(1) The input pin pieces of the magnetic apparatus are pre-formed instead of being bent along the inductor, so that the reliability of the inductor is not influenced, and they are suitable for the case that the thickness of the inductor is relatively low and the structure of the input pin pieces is relatively complex, so that the limitation caused by a bending process in the prior art is avoided.
(2) The hot pressing process aforementioned is an integrally-forming process, and batch production can be carried out in one mold with multiple holes.
(3) According to the manufacturing method aforementioned, the signal pins can be directly formed on the surface of the integrated core assembly, so that the signal pins are provided very thin due to the solidity of the magnetically permeable core, the space utilization is high, and the magnetic loss is low.
(4) The bonding pads on the upper surface and the lower surface of the magnetic apparatus are formed in a method of firstly spraying, secondly performing laser engraving and then performing electroplating, and the bonding pads formed by engraving on the same plane is relatively high in precision, such as +/−0.05 mm. Compared with the bonding pad tolerance (+/−0.2 mm) formed by bending in the prior art, the welding quality can be effectively ensured, and the short-circuit risk is reduced. The flatness of the same plane is determined by the mold, and the flatness tolerance of the mold can be controlled within +/−25 um, so that the power pins and the signal pins on the same surface have enough coplanarity, and the open-circuit risk caused by the coplanarity is effectively reduced.

What is claimed is:

1. An apparatus, comprising:
preformed metal pieces comprising DC voltage pins and windings, a magnetically permeable core and signal pins;
wherein the magnetically permeable core is arranged around at least a part of the windings, and the DC voltage pins are integrated with the magnetically permeable core;
wherein the signal pins are arranged on outer surfaces of the magnetically permeable core through a metallization process; and
wherein the preformed metal pieces and the signal pins are respectively provided with bonding-pad regions and non-pad regions, and the bonding-pad regions on either of an upper surface and a lower surface of the magnetically permeable core are coplanar.

2. The apparatus of claim 1, wherein the non-pad regions of the DC voltage pins are arranged on the selected outer surface or selected outer surfaces of the magnetically permeable core, or are embedded in the magnetically permeable core with a distance of no more than 1 mm to the surface.

3. The apparatus of claim 1, wherein the windings are single-turn windings; and
wherein each of the windings is provided with three vertical sections and two lateral sections which are alternately connected; a distance between the two lateral sections is twice a distance between an upper one of the lateral sections and the upper surface of the magnetically permeable core; and the distance between the two lateral sections is twice a distance between a lower one of the lateral sections and the lower surface of the magnetically permeable core.

4. The apparatus of claim 1, wherein the magnetically permeable core and the preformed metal pieces are integrally formed through a hot-pressing process and annealing treatment.

5. The apparatus of claim 1, wherein the DC voltage pins comprise a ground pin and an input voltage pin, wherein at least a part of a non-pad region of the input voltage pin is overlapped with a non-pad region of the ground pin.

6. The apparatus of claim 1, wherein the DC voltage pins comprise a ground pin, an input voltage pin and a shielding layer, wherein at least a part of a non-pad region of the input voltage pin is overlapped with the shielding layer.

7. The apparatus of claim 6, wherein the shielding layer is provided with a contact region; the ground pin is electrically connected with the contact region; and
wherein an insulation layer is disposed between the input voltage pin and the shielding layer.

8. The apparatus of claim 1, wherein the DC voltage pins comprise ground pins and input voltage pins which are alternately arranged.

9. The apparatus of claim 1, wherein the non-pad regions of the preformed metal pieces are arranged on at least two side surfaces of the magnetically permeable core; the bonding-pad regions of the preformed metal pieces comprise thick-layer lateral-wiring regions and bonding pads, and the thick-layer lateral-wiring regions are electrically connected with the bonding pads and the non-pad regions.

10. The apparatus of claim 1, wherein the bonding-pad regions on the lower surface of the magnetically permeable core comprise a plurality of square bonding pads arranged in a two-dimensional array.

11. The apparatus of claim 1, wherein the magnetically permeable core comprises at least two magnetically permeable core sections; the windings are arranged between the magnetically permeable core sections within grooves formed in the selected magnetically permeable core section or selected magnetically permeable core sections.

12 The apparatus of claim 11, wherein two windings and three magnetically permeable core sections are provided; the magnetically permeable core sections comprise a first magnetically permeable core section, a second magnetically permeable core section and a third magnetically permeable core section, wherein the third magnetically permeable core section is arranged between the first and second magnetically permeable core sections; and
wherein the windings are respectively arranged between the magnetically permeable core sections; either of the windings are arranged within a groove formed on a surface of the respective one of the first and second magnetically permeable core sections.

13. The apparatus of claim 12, wherein the first and second magnetically permeable core sections have a same width, and a width of the third magnetically permeable core section is less than twice a width of the first magnetically permeable core section.

14. The apparatus of claim 12, wherein the first and second magnetically permeable core sections are made of a material with high saturation magnetization, and the third magnetically permeable core section is made of a material with high magnetic permeability.

15. A method comprising:
providing a set of preformed metal pieces comprising input pin pieces and windings;
manufacturing a semi-finished magnetically permeable core;
assembling the input pin pieces, the windings and the semi-finished magnetically permeable core, and then carrying out a hot-pressing process to form an integrated core assembly;
coating at least one outer surface of the integrated core assembly with an insulation layer;
forming openings on the insulation layer, wherein a method comprising laser engraving and/or chemical etching is used; and
forming signal pins in selected ones of the openings by means of a metallization process.

16. The method of claim 15, wherein the preformed metal pieces are respectively provided with bonding-pad regions and non-pad regions, and the bonding-pad regions are exposed at openings which are not selected for forming the signal pins.

17. The method of claim 16, wherein the input pin pieces comprise a ground pin and an input voltage pin, and at least a part of a non-pad region of the input voltage pin is overlapped with and insulated from the ground pin.

18. The method of claim 16, wherein the input pin pieces comprise a ground pin, an input voltage pin and a shielding layer, at least a part of a non-pad region of the input voltage pin is overlapped with and insulated from the shielding layer.

19. The method of claim 15, further comprising: forming a shielding layer on an outer side of the integrated core assembly, wherein at least a part of the shielding layer is overlapped with and insulated from the input pin pieces;
wherein the process of forming the shielding layer is carried out after the process of forming the openings.

20. The method of claim 19, wherein selected one or selected ones of the openings are in a groove-with-via shape comprising groove regions which do not penetrate the insulation layer and via regions which penetrate the insulation layer; the selected DC pin piece or selected input pin pieces are exposed at the via regions; and
wherein the shielding layer is formed within the groove-with-via shaped openings by means of the metallization process; the shielding layer is electrically connected to the selected DC pin piece or selected input pin pieces through the via regions.

21. The method of claim 15, wherein selected one or selected ones of the openings further penetrates the input pin pieces and divided the input pin pieces into a plurality of DC voltage pins, and the DC voltage pins comprise input voltage pins and ground pins.

22. A power module comprising:
a magnetic apparatus comprising preformed metal pieces, a magnetically permeable core and signal pins; and
IPM units comprising power semiconductor devices;
wherein the preformed metal pieces comprise DC voltage pins and windings;
wherein the magnetically permeable core is arranged around at least a part of the windings, and the DC voltage pins are integrated with the magnetically permeable core;
wherein the signal pins are arranged on outer surfaces of the magnetically permeable core through a metallization process;
wherein the preformed metal pieces and the signal pins are respectively provided with bonding-pad regions and non-pad regions, and the bonding-pad regions on either of an upper surface and a lower surface of the magnetically permeable core are coplanar; and
wherein the IPM units are arranged on the upper surface of the magnetically permeable core.

23. The power module of claim 22, further comprising: a wiring board and output capacitors;
wherein the wiring board is arranged at a lower side of the magnetically permeable core;
wherein the output capacitors are arranged on an upper surface of the wiring board or configured within the wiring board; and
wherein the wiring board and the IPM units are electrically connected with the selected preformed metal pieces respectively.

24. The power module of claim 23, wherein the output capacitors are embedded in the wiring board; and
wherein the output capacitors are formed by providing at least two wiring layers in the wiring board and arranging at least one insulating layer with a high dielectric constant between the wiring layers.

25. The power module of claim 22, further comprising a controller; wherein the controller is arranged on a surface of the magnetic apparatus, and the controller is electrically connected with the signal pins.

26. The power module of claim 22, further comprising a plurality of input capacitors;
wherein the DC voltage pins comprise input voltage pins and ground pins;
wherein one end of each of the input capacitors is electrically connected with the selected input voltage pin or selected input voltage pins, and another end of each of the input capacitors is electrically connected with the selected ground pin or selected ground pins; and
wherein at least one of the input capacitors is located on a lower surface of the IPM units.
